(19) United States
(12) Patent Application Publication
(10) Pub. No.: US 2025/0183085 A1
(43) Pub. Date: Jun. 5, 2025

(54) LARGE RANGE HEATED ELECTROSTATIC CHUCK

(71) Applicant: Axcelis Technologies, Inc., Beverly, MA (US)

(72) Inventor: John Baggett, Amesbury, MA (US)

(21) Appl. No.: 18/954,765

(22) Filed: Nov. 21, 2024

Related U.S. Application Data
(60) Provisional application No. 63/604,353, filed on Nov. 30, 2023.

(51) Int. Cl. H01L 21/683; H01J 37/18; H01J 37/317; H01J 37/32; H01L 21/67

(52) U.S. Cl. CPC H01L 21/6833; H01L 21/67248; H01J 37/18; H01J 37/3171; H01J 37/32724

(57) ABSTRACT

A clamping system has a workpiece clamp having a platen to support a workpiece and heating elements for heating the platen to a platen temperature. A cooling plate has cooling features to cool to the cooling plate. A vacuum chamber defines a chamber volume between the platen and the cooling plate. One or more radiation shields within the chamber volume can limit a radiative heat transfer between the platen and the cooling plate. A vacuum source and a gas source are selectively fluidly coupled to the chamber volume. A controller controls the platen temperature in both a high and a low temperature regime by controlling a pressure within the vacuum chamber through the vacuum source and gas source to control a heat transfer between the platen and the cooling plate.

### REFERENCE TO RELATED APPLICATIONS

This application claims the benefit of U.S. Provisional Application Ser. No. 63/604,353 filed Nov. 30, 2023, entitled, “LARGE RANGE HEATED ELECTROSTATIC CHUCK”, the contents of all of which are herein incorporated by reference in their entirety.

### FIELD

The present disclosure relates generally to workpiece processing systems and methods for processing workpieces, and more specifically to a system and method for controlling of a temperature of a workpiece on a thermal electrostatic clamp over a large temperature range.

### BACKGROUND

In semiconductor processing, many operations, such as ion implantation, may be performed on a workpiece or semiconductor wafer. As ion implantation processing technology has advanced, a variety of ion implantation temperatures at the workpiece have been implemented to achieve various implantation characteristics in the workpiece. For example, in conventional ion implantation processing, three temperature regimes are typically considered: cold implants, where process temperatures at the workpiece are maintained at temperatures below room temperature; hot implants, where process temperatures at the workpiece are maintained at high temperatures greater than 200° C.; and so-called quasi-room temperature implants, where process temperatures at the workpiece are maintained at temperatures slightly elevated above room temperature, but lower than those used in high temperature implants, with quasi-room temperature implant temperatures typically ranging from about 50-100° C.

Hot implants, for example, are becoming more common, whereby the process temperature is typically achieved via a dedicated high temperature electrostatic chuck (ESC), also called a heated chuck. The heated chuck holds or clamps the workpiece to a surface thereof during implantation. A conventional high temperature ESC, for example, comprises a heated plate having a set of heaters embedded therein for heating the workpiece to the process temperature (e.g., 200° C.-600° C.).

In automated systems, the heated plate of the high temperature ESC is typically coupled to a mounting flange, whereby the mounting flange further couples the high temperature ESC to a robot for selective transport of the workpiece. The heated plate is conventionally thermally isolated from the mounting flange in order to prevent thermal losses from the heated plate to the mounting flange, as well as to protect the robot and associated components from damage due to the high temperatures.

### SUMMARY

The present disclosure thus provides a system, apparatus, and method for clamping and controlling a temperature of an electrostatic clamp. Accordingly, the following presents a simplified summary of the disclosure in order to provide a basic understanding of some aspects of the invention. This summary is not an extensive overview of the invention. It is intended to neither identify key or critical elements of the invention nor delineate the scope of the invention. Its purpose is to present some concepts of the invention in a simplified form as a prelude to the more detailed description that is presented later.

In accordance with one aspect of the disclosure, a clamping system is provided for semiconductor processing of a workpiece. The clamping system, for example, comprises a workpiece clamp having a platen defining a support surface configured to support the workpiece. The workpiece clamp, for example, further comprises one or more heating elements configured to heat the platen to a platen temperature, as well as a cooling plate having one or more cooling features configured to selectively cool the cooling plate to a cooling plate temperature. The workpiece clamp, for example, further comprises one or more electrodes associated with the platen and configured to selectively electrostatically clamp the workpiece to the platen.

Further, the workpiece clamp comprises a vacuum chamber operably coupled to the platen and the cooling plate, wherein the vacuum chamber defines a chamber volume between the platen and the cooling plate. The vacuum chamber, for example, comprises one or more radiation shields disposed within the chamber volume, wherein the one or more radiation shields are configured to limit a radiative heat transfer between the platen and the cooling plate.

The clamping system, for example, further comprises a vacuum source selectively fluidly coupled to the chamber volume and a gas source selectively fluidly coupled to the chamber volume. The vacuum source, for example, is configured to selectively evacuate the chamber volume, and the gas source is configured to selectively supply a gas to the chamber volume. A vacuum chamber valve, for example, selectively fluidly couples the chamber volume to each of the vacuum source and the gas source.

Further, in accordance with one example, a controller is further provided and configured to control the platen temperature in a high temperature regime and a low temperature regime. The platen temperature, for example, is controlled via a control of the one or more heating elements, as well as a pressure within the vacuum chamber via a control of the vacuum chamber valve. As such, the controller is configured to selectively control a convective heat transfer and a conductive heat transfer between the platen and the cooling plate in the high temperature regime and the low temperature regime.

To the accomplishment of the foregoing and related ends, the disclosure comprises the features hereinafter fully described and particularly pointed out in the claims. The following description and the annexed drawings set forth in detail certain illustrative embodiments of the invention. These embodiments are indicative, however, of a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

FIG. 1 is a schematic view of a workpiece clamping system operating in a high temperature regime in accordance with various examples of the present disclosure.

FIG. 2 is a schematic view of a workpiece clamping system having a vacuum chamber with no thermal shields in accordance with various examples of the present disclosure.

FIG. 3A is a schematic view of a workpiece clamp operating in a high temperature regime in accordance with various examples of the present disclosure.

FIG. 3B is a schematic view of a workpiece clamp operating in a low temperature regime in accordance with various examples of the present disclosure.

FIG. 4 illustrates a block diagram of ion implantation system in accordance with various examples of the present disclosure.

FIG. 5 is a block diagram illustrating an exemplified method for temperature control of a workpiece according to various examples of the disclosure.

### DETAILED DESCRIPTION

The present disclosure is directed generally toward workpiece processing systems and apparatuses for processing workpieces at various temperatures. More particularly, the disclosure is directed toward an electrostatic clamping system and method for clamping a workpiece in an ion implantation system, wherein an electrostatic chuck (ESC) is configured to selectively control a heating of a workpiece that is clamped thereto over a large temperature range. Accordingly, the present invention will now be described with reference to the drawings, wherein like reference numerals may be used to refer to like elements throughout. It should be understood that the description of these aspects are merely illustrative and that they should not be interpreted in a limiting sense. In the following description, for purposes of explanation, numerous specific details are set forth in order to provide a thorough understanding of the present invention. It will be evident to one skilled in the art, however, that the present invention may be practiced without these specific details.

The present disclosure appreciates that operation of a workpiece clamp, such as an electrostatic chuck, over a large variety of temperature ranges can be desirable for various semiconductor processes performed on a semiconductor workpiece clamped thereto. For example, in some processes, such as high temperature ion implantation, processing of workpieces in a high temperature regime at substantially high temperatures (e.g., greater than approximately 200° C.) can be desirable. In other instances, processing of workpieces in a low temperature regime at low temperatures such as operations at so-called quasi-room temperature can be desirable. For example, quasi-room temperature can be considered as being less than 200° C., such as between approximately room temperature (RT) and approximately 100° C. The present disclosure provides an architecture of a workpiece clamping system that is configured for both the high temperature regime and the low temperature regime, whereby changing between the high temperature regime and the low temperature regime is simple and efficient.

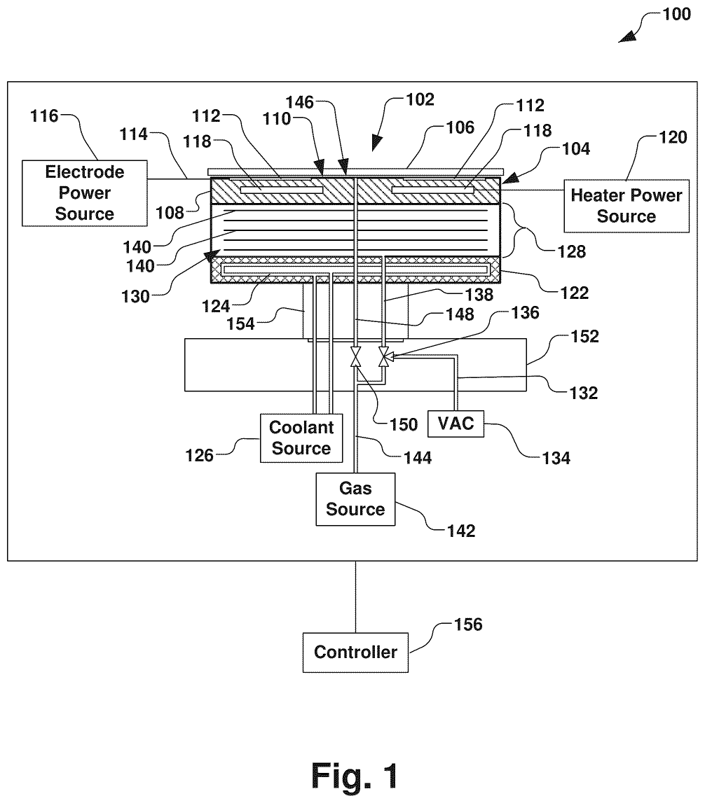

Referring now to the Figures, FIG. 1 illustrates an example of a clamping system 100, whereby a workpiece clamp 102, such as an ESC 104, is provided for selectively clamping a workpiece 106 thereto. It shall be noted that while the workpiece clamp 102 is described in the present example as being an ESC 104, other examples, while not shown, are also contemplated, such as a mechanical clamp, or simply a support having no clamping capability other than gravity, and all such workpiece clamps are contemplated as falling within the scope of the present disclosure.

The workpiece clamp 102, for example, can be further configured to selectively heat the workpiece 106, such as in instances where a high temperature ion implantation can be performed on the workpiece, and whereby a temperature of the workpiece can be readily controlled. For example, the workpiece clamp 102 comprises a platen 108 defining a support surface 110 configured to support the workpiece 106 thereon.

In the example shown in FIG. 1, the ESC 104 comprises one or more clamping electrodes 112 associated with the platen 108, wherein the electrostatic clamp is configured to selectively electrostatically attract the workpiece 106 to the support surface 110 (also called a clamping surface) based on an electrical current 114 supplied to the one or more clamping electrodes, such as provided by an electrode power source 116. The one or more clamping electrodes 112 of the ESC 104, in conjunction with a material composition of the platen 108, for example, are configured to electrostatically clamp the workpiece 106 to the support surface 110, thereof. The platen 108, for example, can be comprised of one or more ceramics, such as one or more of alumina, aluminum nitride, boron nitride, and quartz.

In the one example, the workpiece clamp 102 further comprises one or more heating elements 118, wherein the one or more heating elements are configured to selectively heat the platen 108 to a platen temperature. In one example, the one or more heating elements 118 are embedded in the platen 108. The one or more heating elements 118, for example, are selectively powered by a heater power source 120 and can comprise one or more resistive heaters, one or more heat lamps, or various other heating devices configured to selectively heat the platen 108, and all such heating elements are contemplated as falling within the scope of the present disclosure.

The workpiece clamp 102 of the present example further comprises a cooling plate 122 having one or more cooling features 124 configured to selectively cool the cooling plate to a cooling plate temperature. The one or more cooling features 124, for example, comprise one or more cooling channels defined in the cooling plate 122 and are configured to selectively circulate a cooling fluid (e.g., a liquid such as water) provided by a coolant source 126 thereto.

In accordance with one example aspect of the present disclosure, the workpiece clamp 102 further comprises a vacuum chamber 128 operably coupled to the platen 108 and the cooling plate 122. The vacuum chamber 128, for example, generally defines a chamber volume 130 between the platen 108 and the cooling plate 122, whereby a chamber environment is present within the chamber volume 130. For example, a vacuum conduit 132 fluidly couples a vacuum source 134 to a vacuum chamber valve 136, whereby the vacuum chamber valve is configured to selectively fluidly couple the chamber volume 130 to the vacuum source. As such, the vacuum source 134 is configured to selectively evacuate the chamber volume 130 to provide the chamber environment at a substantial vacuum via a control of the vacuum chamber valve 136. The vacuum source 134, for example, can comprise a vacuum pump (not shown) or a vacuum environment associated with a process chamber, as will be discussed further infra. As illustrated in FIG. 1, a chamber conduit 138 further fluidly couples the chamber volume 130 of the vacuum chamber 128 to the vacuum chamber valve 136. It is to be appreciated that while not shown, one or more of the vacuum conduit 132 and the chamber conduit 138 may comprise one or more channels, tubes, or other passageways configured to selectively fluidly couple the vacuum chamber 128 to the vacuum source 134 via the vacuum chamber valve 136.

In accordance with another example aspect of the disclosure, the vacuum chamber 128 further comprises one or more radiation shields 140 disposed within the chamber volume 130. The one or more radiation shields 140, for example, are configured to limit a radiative heat transfer between the platen 108 and the cooling plate 122. The present disclosure contemplates any number of radiation shields 140 being provided to sufficiently limit thermal radiation between the platen 108 and cooling plate 122.

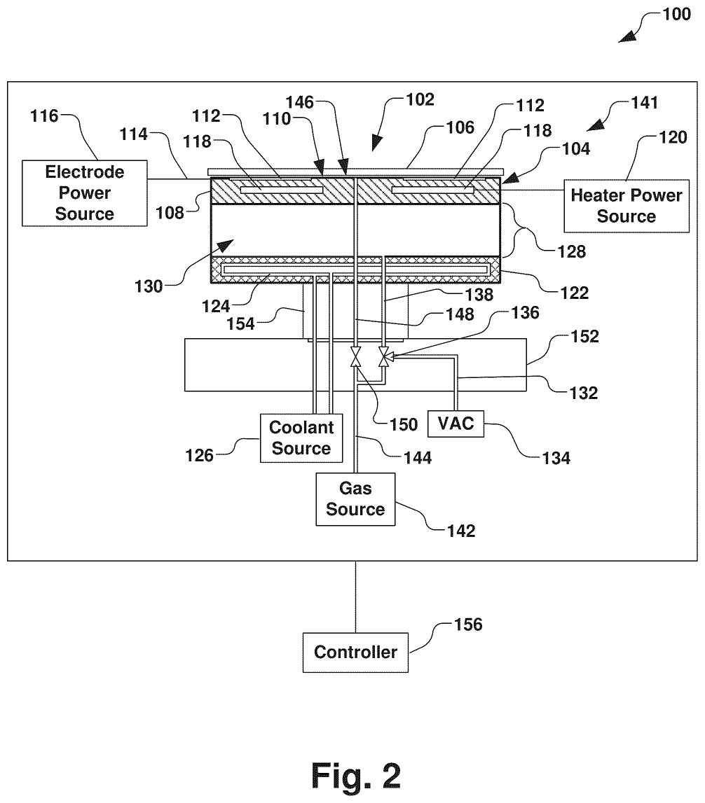

The present disclosure further contemplates an example where no radiation shields 140 shown in FIG. 1 are provided within the vacuum chamber 128. For example, FIG. 2 illustrates the workpiece clamp 102 in an alternative configuration 141, wherein the vacuum chamber 128 is devoid of the one or more radiation shields 140 of FIG. 1. For example, the alternative configuration 141 of the workpiece clamp 102 shown in FIG. 2 can be advantageous when radiative heat transfer can be considered minimal or inconsequential compared to conductive or convective heat transfer between the platen 108 and the cooling plate 122. As such, a complexity of the workpiece clamp 102 can be minimized.

Furthermore, the clamping system 100 of FIGS. 1-2 further comprises a gas source 142, whereby the gas source is further fluidly coupled to the vacuum chamber valve 136 via a gas conduit 144. For example, the gas source 142 is configured to selectively supply a conductive gas to the chamber volume 130 through the chamber conduit 138 and the gas conduit 144 via a control of the vacuum chamber valve 136. It is again to be appreciated that while not shown, the gas conduit 144 may comprise one or more channels, tubes, or other passageways configured to selectively fluidly couple the vacuum chamber 128 to the gas source 142 via the vacuum chamber valve 136.

The conductive gas supplied by the gas source 142, for example, comprises a thermally conductive and/or inert gas, such as nitrogen (N₂). The conductive gas can be supplied from the gas source 142 to the vacuum chamber 128 at a predetermined pressure (e.g., approximately 5 torr) when the platen temperature is desired to be maintained in the low temperature regime, thereby effectuating the convective heat transfer and the conductive heat transfer between the platen 108 and the cooling plate 122 via the conductive gas.

In the present example, vacuum chamber valve 136 comprises a three-way valve, whereby the vacuum chamber valve is configured to selectively fluidly couple a selected one of the vacuum source 134 or the gas source 142 to chamber volume 130 of the vacuum chamber 128. While a three-way valve is illustrated as one example of the vacuum chamber valve 136, it is to be appreciated that any number of valves and/or conduits may be provided to yield a similar selective fluid coupling of the vacuum source 134 or the gas source 142 to the vacuum chamber 128, and all such configurations are contemplated as falling within the scope of the present disclosure. For example, FIGS. 1-2 illustrates the chamber conduit 138 as a single conduit fluidly coupling the vacuum chamber valve 136 to the vacuum chamber 128, whereby the vacuum chamber valve 136 is shown as a three-way valve. However, while not shown, it is to be appreciated that the vacuum chamber valve 136 and/or the chamber conduit 138 may comprise a plurality of valves and/or conduits respectively selectively fluidly coupling the vacuum chamber 128 to the vacuum source 134 and the gas source 142, and all such combinations thereof are contemplated as falling within the scope of the present disclosure.

In accordance with another example, the gas source 142 can be further selectively fluidly coupled to a backside gap 146 defined between the workpiece 106 and the support surface 110 of the platen 108 via a backside gas conduit 148. As such, the gas source 142 can be configured to selectively supply the conductive gas to the backside gap 146 to thermally couple the workpiece 106 to the platen 108 via the conductive gas. For example, a backside gas valve 150 is provided to selectively fluidly couple the backside gap 146 to the gas source 142 via the gas conduit 144, whereby the conductive gas can be selectively provided to the backside side based on the desired processing of the workpiece 106.

It is again to be appreciated that while not shown, the backside gas conduit 148 and the gas conduit 144 may comprise one or more channels, tubes, or other passageways configured to selectively fluidly couple the backside gap 146 to the gas source 142 via the backside gas valve 150. For example, while the gas conduit 144 is illustrated as commonly fluidly coupling both of the vacuum chamber valve 136 and the backside gas valve 150 to the gas source 142, it is to be appreciated that the gas source and gas conduit may comprise any number of gas sources and conduits configured to respectively fluidly couple the gas source(s) to the vacuum chamber valve and the backside gas valve, and all such combinations thereof are contemplated as falling within the scope of the present disclosure.

In accordance with another example, the workpiece clamp 102 is further operably coupled to a manipulator apparatus 152, such as a robot or other automation apparatus, whereby the manipulator apparatus is configured for selectively translating or otherwise moving the workpiece clamp before, during, and/or after processing of the workpiece 106. For example, the manipulator apparatus 152 can be configured to selectively translate the workpiece 106 through a process medium such as an ion beam, as will be discussed in greater detail infra.

A mounting flange 154, for example, can operably couple the workpiece clamp 102 to the manipulator apparatus 152, whereby the mounting flange provides various dynamic and/or static connections (e.g., mechanical, electrical, and/or fluid connections) between the workpiece clamp and the manipulator apparatus.

In accordance with yet another aspect of the present disclosure, the controller 156 is further provided and configured to selectively control various features of the clamping system 100. For example, the electrical current provided to the one or more clamping electrodes 112 via a control of the electrode power source 116, thereby selectively attracting the workpiece 106 to the support surface 110 for electrostatic clamping, thereto.

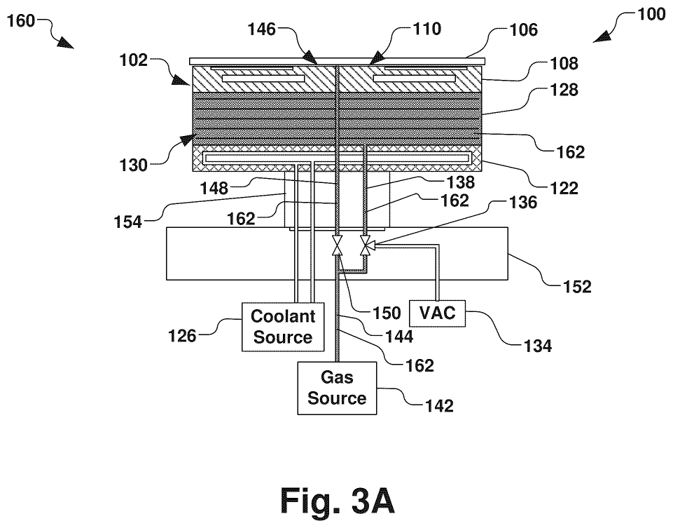

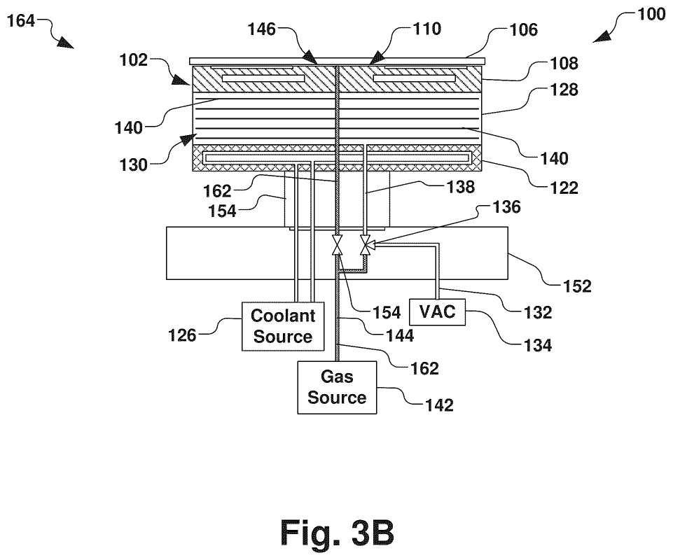

FIG. 3A, for example, illustrates a low temperature configuration 160 of the clamping system 100, whereby convective heat transfer and conductive heat transfer between the platen 108 and the cooling plate 122 is maximized or otherwise effectuated in the low temperature regime by a conductive gas 162 provided in the vacuum chamber 128 from the gas source 142 through the gas conduit 144 and the chamber conduit 138. For example, in the low temperature configuration 160, the vacuum chamber valve 136 is configured to fluidly couple the gas source 142 to the chamber volume 130 of the vacuum chamber 128, while decoupling the vacuum source 134 therefrom. As such, the conductive gas 162 thermally couples the platen 108 to the cooling plate 122, whereby the coolant fluid supplied by the coolant source 126 to the cooling plate can act as a heat sink to remove heat from the workpiece 106 associated with the semiconductor processing thereof.

In the example shown in FIG. 3B, a high temperature configuration 164 of the clamping system 100 is illustrated, whereby convective heat transfer and conductive heat transfer between the platen 108 and the cooling plate 122 is minimized or otherwise prevented in the high temperature regime by evacuating the vacuum chamber 128. In the high temperature configuration 164, for example, the vacuum chamber valve 136 is configured to fluidly decouple the gas source 142 from the chamber volume 130 of the vacuum chamber 128, while fluidly coupling the vacuum source 134 thereto via the vacuum conduit 132 and the chamber conduit 138. Accordingly, the conductive gas 162 within the chamber volume 130 shown in FIG. 3A is evacuated from the chamber volume 130 in the high temperature configuration 164 of the clamping system 100 shown in FIG. 3B, thus thermally decoupling the platen 108 from the cooling plate 122 in the high temperature regime. As such, it is to be appreciated that any substantial heat transfer between the platen 108 and the cooling plate 122 would be from thermal radiation due to the vacuum environment within the chamber volume 130, whereby the one or more radiation shields 140 discussed above can advantageously limit such radiative heat transfer between the cooling plate and the platen.

In accordance with another example, the present disclosure can advantageously thermally isolate or otherwise limit heat transfer between the workpiece clamp 102 and other apparatuses operably coupled thereto, such as the manipulator apparatus 152 and the mounting flange 154 when operating in the high temperature regime. For example, in the high temperature configuration 164 shown in FIG. 3B, heat transfer between the platen 108 and the mounting flange 154 and the manipulator apparatus 152 can be substantially reduced by evacuating the chamber volume 130, thereby substantially preventing thermal damage to the manipulator apparatus. In other words, conductive and convective transfer of thermal energy present at the platen 108, whether from processing of the workpiece 106 through a process medium, or from the one or more heating elements 118, can be limited from transferring to the mounting flange 154 and manipulator apparatus 152 in the high temperature regime by the selective evacuation of the chamber volume provided herein.

The present disclosure thus provides a clamping system 100 that can be configured to advantageously utilize the same workpiece clamp 102 in both the low temperature configuration 160 of FIG. 3A in the low temperature regime and the high temperature configuration 164 of FIG. 3B in the high temperature regime by a relatively simple configuration of the vacuum chamber valve 136. Conventionally, adequate control of the temperature of a single workpiece clamp in both the high temperature regime and the low temperature regime has been difficult to attain, as not enough thermal loss was typically present to adequately control the temperature of the ESC at quasi-room temperatures, while also being able utilize the single workpiece clamp in the high temperature regime, without significant modifications to the workpiece clamp, or replacement thereof.

Referring again to FIGS. 1-2, and in accordance with yet another aspect of the present disclosure, the controller 156 is configured to provide overall control of the clamping system 100. For example, the controller 156 is configured to selectively control the electrical current provided to the one or more clamping electrodes 112 via a control of the electrode power source 116, thereby selectively attracting the workpiece 106 to the support surface 110 for electrostatic clamping, thereto. The controller 156, for example, is further configured to control the temperature of the platen 108 in both the high temperature regime and the low temperature regime via a control of one or more of the vacuum chamber valve 136, backside gas valve 150, heater power source 120, coolant source 126, gas source 142, and vacuum source 134, as described above. In one example, the high temperature regime is greater than approximately 200° C. (e.g., between approximately 200-600° C. or higher), and the low temperature regime is less than the high temperature regime, such as at quasi-room temperature of approximately 100° C. or less.

While not shown, in accordance with one example, one or more thermal monitoring devices may be provided to determine a temperature of the workpiece 106 or the platen 108 for temperature feedback to the controller 156. The one or more thermal monitoring devices can be configured to directly contact the workpiece 106. For example, the one or more direct contact thermal devices can comprise one or more of a thermocouple (TC) and a resistance temperature detector (RTD).

The controller 156, for example, is configured to control the one or more heating elements 118, such as via a control of electrical power to the one or more heating elements from the heater power source 120. The controller 156, for example, is further configured to control a pressure within the chamber volume 130 of the vacuum chamber 128 via a control of the vacuum source 134 and the gas source 142, thereby selectively controlling a convective heat transfer and a conductive heat transfer between the platen 108 and the cooling plate 122 in both the high temperature regime and the low temperature regime.

It is again noted that the one or more radiation shields 140 generally limit radiative heat transfer between the platen 108 and the cooling plate 122, particularly when the chamber environment is at a substantial vacuum when the clamping system 100 is configured to operate in the high temperature regime illustrated in FIG. 3B, thus further mitigating convective and conductive heat loss from the workpiece clamp 102 to the mounting flange 154 and manipulator apparatus 152.

The controller 156, for example, is further configured to supply the conductive gas 162 from the gas source 142 to the vacuum chamber 128 at the predetermined pressure when the platen temperature is in the low temperature regime, as illustrated in FIG. 3A, thereby effectuating the convective heat transfer and the conductive heat transfer between the platen 108 and the cooling plate 122.

Accordingly, the clamping system 100 of the present disclosure can be configured to achieve and control a temperature of the workpiece 106 over a larger temperature range via the workpiece clamp 102 with only minor alterations to the configuration of the clamping system. Thus, the present disclosure mitigates the conventional need to replace workpiece clamps based on a change in the desired temperature regime in which they are operated.

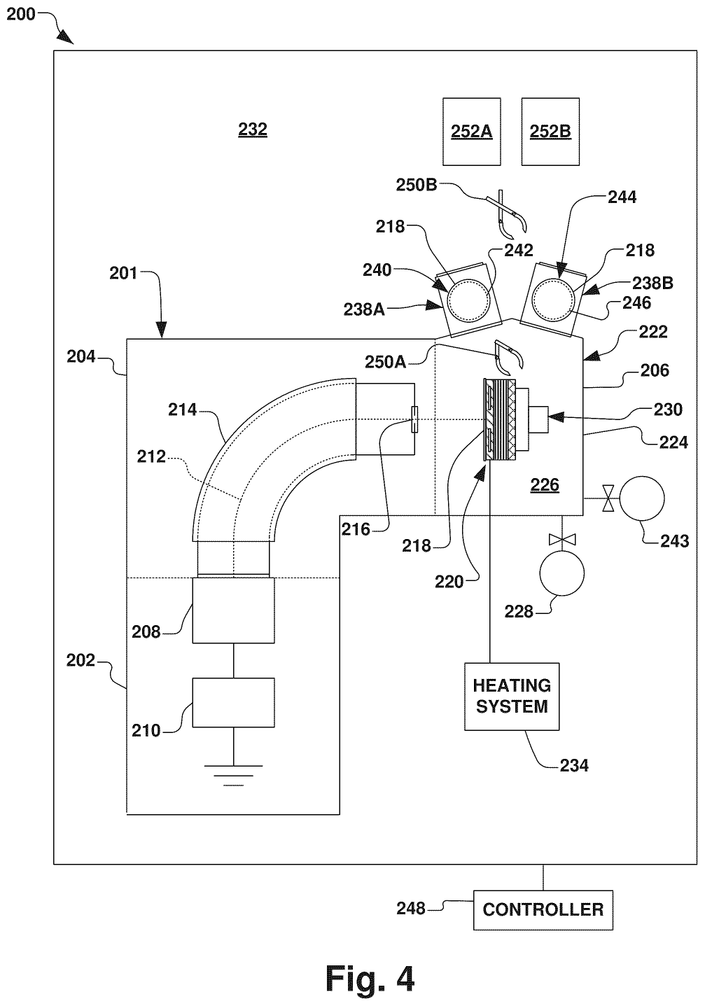

In accordance with yet another example of the disclosure, FIG. 4 illustrates an example of an ion implantation system 200 configured for use with the clamping system 100 of FIGS. 1, 2, 3A, and 3B. The ion implantation system 200, for example, is configured to implant ions into a workpiece at a process temperature having a large temperature range, such as in the low temperature regime and the high temperature regime discussed above. The process temperature, for example, is, at least in part, achieved and maintained at the workpiece clamp 102 that supports the workpiece 106 of FIGS. 1-2 concurrent with the ion implantation.

In accordance with various aspects of the present disclosure, the ion implantation system 200 of FIG. 4 comprises various components in the present example, however various other types of vacuum-based semiconductor processing systems are also contemplated, such as plasma processing systems, or other semiconductor processing systems. The ion implantation system 200, for example, comprises a terminal 202, a beamline assembly 204, and an end station 206.

Generally speaking, an ion source 208 in the terminal 202 is coupled to a power supply 210 to ionize a dopant gas into a plurality of ions and to form an ion beam 212. The ion beam 212 in the present example is directed from the terminal 202 to the beamline assembly 204, whereby the ion beam passes through a mass analysis apparatus 214 and out an aperture 216 towards the end station 206. In the end station 206, the ion beam 212 bombards a workpiece 218 (e.g., a substrate such as a silicon wafer, a display panel, etc.), such as the workpiece 106 of FIGS. 1, 2, 3A, and 3B which is selectively clamped or mounted to a chuck 220. The chuck 220 of FIG. 4, for example, may comprise the workpiece clamp 102 (e.g., an ESC) of FIGS. 1, 2, 3A, and 3B described above, wherein the chuck is configured to selectively control a temperature of the workpiece 218. Once embedded into the lattice of the workpiece 218 of FIG. 4, for example, the implanted ions change the physical and/or chemical properties of the workpiece. Because of this, ion implantation is used in semiconductor device fabrication and in metal finishing, as well as various applications in materials science research.

The ion beam 212 of the present disclosure can take any form, such as a pencil or spot beam, a ribbon beam, a scanned beam, or any other form in which ions are directed toward end station 206, and all such forms are contemplated as falling within the scope of the disclosure.

According to one exemplified aspect, the end station 206 comprises a process chamber 222, such as a vacuum chamber 224, wherein a process environment 226 is associated with the process chamber. The process environment 226 generally exists within the process chamber 222, and in one example, comprises a vacuum produced by a vacuum source 228 (e.g., a vacuum pump) coupled to the process chamber and configured to substantially evacuate the process chamber.

In one example, the ion implantation system 200 is configured to provide a high temperature ion implantation, wherein the workpiece 218 is heated to a process temperature (e.g., approximately 200-600° C. or greater). Thus, in the present example, the chuck 220 comprises at least the workpiece clamp 102 of the clamping system 100 of FIGS. 1-2. Various other components of the clamping system 100 of FIGS. 1-2 are contemplated as being integrated with the ion implantation system 200 of FIG. 4, and any combination thereof is contemplated as falling within the scope of the present disclosure.

The chuck 220 of FIG. 4, for example, is configured to support and retain the workpiece 218 while further heating the workpiece within the process chamber 222 prior to, during, and/or after the exposure of the workpiece to the ion beam 212. The chuck 220, for example, comprises an electrostatic chuck configured to heat the workpiece 218 to a wide range of processing temperatures, such as those described above, and is selectively positioned within the process chamber 222 by a manipulator apparatus 230, such as the manipulator apparatus 152 of FIGS. 1-2. For example, the chuck 220 of FIG. 4 is configured to clamp and heat the workpiece in both the low temperature regime and the high temperature regime, wherein the high temperature regime in the present example is considerably greater than an ambient or atmospheric temperature of the surroundings or external environment 232 (e.g., also called an “atmospheric environment”). A heating system 234 may be further provided, wherein the heating system is configured to heat the chuck 220 and, in turn, the workpiece 218 residing thereon to the desired processing temperature. The heating system 234, for example, is configured to selectively heat the workpiece 218 via the one or more heating elements 118 disposed within the platen 108 of the workpiece clamp 102 of FIGS. 1-2, or any other heaters (not shown).

For some implants in the high temperature regime, for example, the workpiece 218 may allowed to “soak” on the chuck 220 of FIG. 4 within the vacuum of the process environment 226 until the desired temperature is reached. Alternatively, in order to increase cycle time through the ion implantation system 200, the workpiece 218 may be pre-heated in one or more chambers 238A, 238B (e.g., one or more load lock chambers) operatively coupled to the process chamber 222 via a pre-heat apparatus 240. The pre-heat apparatus 240, for example, may comprise a pre-heat support 242 configured similar to the chuck 220.

Depending on the tool architecture, process, and desired throughput, the workpiece 218 may be preheated to the first temperature via the pre-heat apparatus 240, wherein the first temperature is equal to or lower than the process temperature, thus allowing for a final thermal equalization on the chuck 220 inside the vacuum chamber 224. Such a scenario allows the workpiece 218 to lose some heat during transfer to the process chamber 222, wherein final heating to the process temperature is performed on the chuck 220. Alternatively, the workpiece 218 may be preheated via the pre-heat apparatus 240 to a first temperature that is higher than the process temperature. Accordingly, the first temperature would be optimized so that cooling of the workpiece 218 during transfer to the process chamber 222 is just enough for the workpiece to be at the desired process temperature as it is clamped onto the chuck 220.

In order to accurately control and/or accelerate the thermal response and enable an additional mechanism for heat transfer, the back side of the workpiece 218 is brought into conductive communication with the chuck 220. This conductive communication is achieved, for example, through a pressure-controlled gas interface (also called “back side gas”) between the chuck 220 and the workpiece 218. The back side gas, for example, can be provided by a gas source 243, such as the gas source 142 of FIGS. 1-2. Pressure of the back side gas, for example, is generally limited by the electrostatic force of the chuck 220 shown in FIG. 4, and can be generally kept in the range of 5-20 Torr. In one example, the back side gas interface thickness (e.g., the distance between the workpiece 218 and the chuck 220) is controlled on the order of microns (typically 5-20 μm), and as such, the molecular mean free path in this pressure regime becomes large enough for the interface thickness to push the system into the transitional and molecular gas regime.

In accordance with another aspect of the disclosure, chamber 238B comprises a cooling apparatus 244 configured to cool the workpiece when the workpiece 218 is disposed within the chamber 238B subsequent to being implanted with ions during ion implantation. The cooling apparatus 244, for example, may comprise a chilled workpiece support 246, wherein the chilled workpiece support is configured to actively cool the workpiece 218 residing thereon via thermal conduction. The chilled workpiece support 246, for example, comprises a cold plate having a one or more cooling channels passing therethrough, wherein a cooling fluid passing through the cooling channel substantially cools the workpiece 218 residing on a surface of the cold plate. The chilled workpiece support 246 may comprise other cooling mechanisms, such as Peltier coolers or other cooling mechanisms known to one of ordinary skill.

In accordance with another exemplified aspect, a controller 248 is further provided and configured to selectively control one or more of the chuck 220, the vacuum source 228, the heating system 234, the pre-heat apparatus 240, the gas source 243, and the cooling apparatus to selectively heat or cool the workpiece 218 respectively residing thereon. The controller 248, for example, can comprise the controller 156 of FIGS. 1, 2, 3A, and 3B, and may be further configured to heat the workpiece 218 in chamber 238A of FIG. 4 via the pre-heat apparatus 240, to heat the workpiece to a predetermined temperature in the processing chamber 222 via the chuck 220 and heating system 234, to implant ions into the workpiece via the ion implantation system 200, to cool the workpiece in chamber 238B via the cooling apparatus 244, and to selectively transfer the workpiece between the external environment 232 and the process environment 226 via one or more workpiece transfer apparatuses 250A, 250B.

In one example, the workpiece 218 may be further delivered to and from the process chamber 222 such that the workpiece is transferred between a selected front opening unified pod (FOUP) 252A, 252B and chambers 238A, 238B via workpiece transfer apparatus 250B, and further transferred between the chambers 238A, 238B and the chuck 220 via workpiece transfer apparatus 250A. The controller 248, for example, is further configured to selectively transfer the workpiece between the FOUPs 252A, 252B, chambers 238A, 238B, and chuck 220 via a control of the respective workpiece transfer apparatus 250A, 250B.

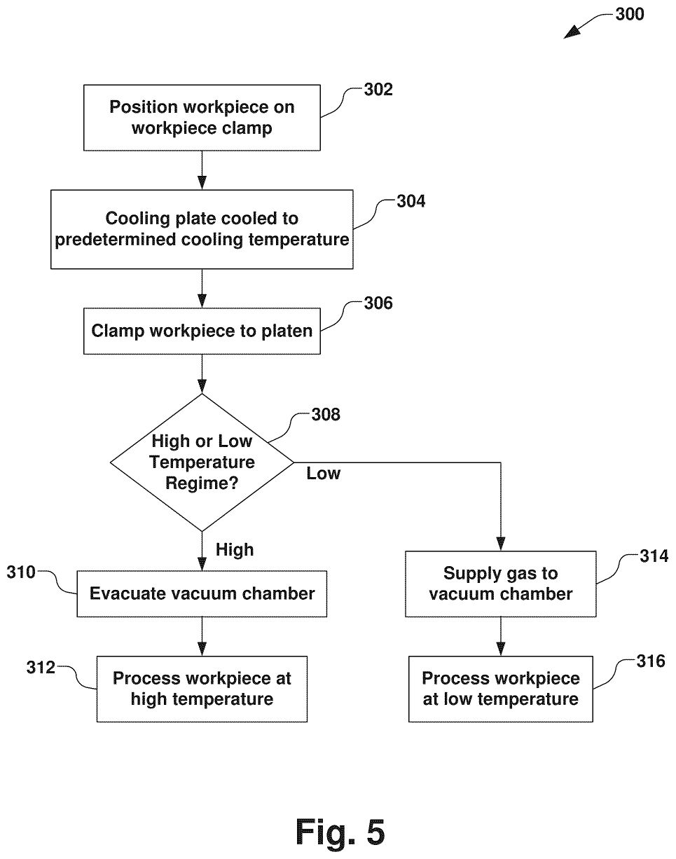

In another aspect of the disclosure, FIG. 5 illustrates a method 300 for controlling a temperature of a workpiece. It should be noted that while exemplified methods are illustrated and described herein as a series of acts or events, it will be appreciated that the present disclosure is not limited by the illustrated ordering of such acts or events, as some steps may occur in different orders and/or concurrently with other steps apart from that shown and described herein, in accordance with the disclosure. In addition, not all illustrated steps may be required to implement a methodology in accordance with the present disclosure. Moreover, it will be appreciated that the methods may be implemented in association with the systems illustrated and described herein as well as in association with other systems not illustrated.

The method 300 shown in FIG. 5, for example, control the temperature of a workpiece in a semiconductor processing system. In act 302, a workpiece is positioned on a platen of a workpiece clamp, wherein the workpiece clamp comprises a vacuum chamber disposed between the platen and a cooling plate thereof. The vacuum chamber can comprise a chamber volume having one or more radiation shields disposed therein, or the chamber may be devoid of radiation shields. In act 304, the cooling plate is cooled to a predetermined cooling temperature. In act 306, the workpiece is clamped to the platen.

In act 308, an operation of the semiconductor processing is selected in one of a high temperature regime and a low temperature regime. In act 310, when the operation of the semiconductor process is in the high temperature regime, the vacuum chamber is evacuated, thereby defining a vacuum within the chamber volume and thermally isolating the cooling plate from the platen via the vacuum within the chamber volume and in some examples, the one or more radiation shields. In act 312, the workpiece is processed through a process medium, such as an ion beam, in the high temperature regime.

In act 314, when the operation of the semiconductor process is in the low temperature regime, a conductive gas is supplied to the chamber volume thereby effectuating thermal conduction and thermal convection between the platen and the cooling plate. In act 316, the workpiece is processed through a process medium, such as an ion beam, in the low temperature regime.

Although the disclosure has been shown and described with respect to a certain preferred embodiment or embodiments, it is obvious that equivalent alterations and modifications will occur to others skilled in the art upon the reading and understanding of this specification and the annexed drawings. In particular regard to the various functions performed by the above described components (assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplified embodiments of the disclosure. In addition, while a particular feature of the disclosure may have been disclosed with respect to only one of several embodiments, such feature may be combined with one or more other features of the other embodiments as may be desired and advantageous for any given or particular application.

What is claimed is:

1. A clamping system for semiconductor processing, the clamping system comprising:
a workpiece clamp comprising:
a platen defining a support surface configured to support a workpiece thereon;
one or more heating elements configured to heat the platen to a platen temperature;
a cooling plate having one or more cooling features configured to selectively cool the cooling plate to a cooling plate temperature; and
a vacuum chamber operably coupled to the platen and the cooling plate, wherein the vacuum chamber defines a chamber volume between the platen and the cooling plate;
a vacuum source selectively fluidly coupled to the chamber volume;
a gas source selectively fluidly coupled to the chamber volume and configured to selectively supply a gas thereto;
a vacuum chamber valve, wherein the vacuum chamber valve selectively fluidly couples the chamber volume to each of the vacuum source and the gas source; and
a controller configured to control the platen temperature in a high temperature regime and a low temperature regime via a control of the one or more heating elements, wherein the controller is further configured to control a pressure within the vacuum chamber via a control of the vacuum chamber valve, thereby selectively controlling a heat transfer between the platen and the cooling plate in the high temperature regime and the low temperature regime.

2. The clamping system of claim 1, wherein the vacuum chamber comprises one or more radiation shields disposed within the chamber volume and configured to limit a radiative heat transfer between the platen and the cooling plate.

3. The clamping system of claim 1, wherein the high temperature regime is greater than approximately 200° C., and wherein the low temperature regime is less than the high temperature regime.

4. The clamping system of claim 3, wherein the low temperature regime ranges between approximately room temperature and approximately 100° C.

5. The clamping system of claim 1, wherein the workpiece clamp comprises an electrostatic clamp having one or more electrodes associated with the platen, wherein the electrostatic clamp is configured to selectively electrostatically attract the workpiece to the support surface based on an electrical current supplied to the one or more electrodes.

6. The clamping system of claim 5, further comprising an electrode power source operably coupled to the one or more electrodes and configured to supply the electrical current thereto, wherein the controller is further configured control the electrical current via a control of the electrode power source.

7. The clamping system of claim 1, wherein the controller is further configured to selectively evacuate the vacuum chamber when the platen temperature is in the high temperature regime, thereby minimizing convective heat transfer and conductive heat transfer between the platen and the cooling plate.

8. The clamping system of claim 1, wherein the vacuum chamber valve comprises a three-way valve configured to selectively fluidly couple the chamber volume to each of the vacuum source and the gas source.

9. The clamping system of claim 1, wherein the vacuum source comprises a process chamber having a vacuum environment associated therewith.

10. The clamping system of claim 1, wherein the vacuum source comprises a vacuum pump.

11. The clamping system of claim 1, wherein the gas source is configured to supply the gas to the chamber volume at a predetermined pressure, and wherein the controller is further configured to selectively supply the gas from the gas source to the vacuum chamber at the predetermined pressure when the platen temperature is in the low temperature regime, thereby effectuating convective heat transfer and conductive heat transfer between the platen and the cooling plate.

12. The clamping system of claim 11, wherein the predetermined pressure is greater than approximately 5 torr.

13. The clamping system of claim 1, wherein the gas comprises a thermally conductive gas.

14. The clamping system of claim 1, wherein the one or more cooling features comprise one or more cooling channels defined in the cooling plate and configured to circulate a cooling fluid therein.

15. The clamping system of claim 1, further comprising a manipulator apparatus and a mounting flange, wherein the cooling plate is operably coupled to the manipulator apparatus via the mounting flange, and wherein the manipulator apparatus is configured to selectively translate the workpiece clamp.

16. An ion implantation system comprising:
an ion source configured to define an ion beam;
a beamline assembly configured to receive the ion beam from the ion source;
an end station configured to receive the ion beam from the beamline assembly along a beam path;
a workpiece clamp selectively positioned within the end station along the beam path, the workpiece clamp comprising:
a platen defining a support surface configured to support a workpiece thereon;
one or more heating elements configured to heat the platen to a platen temperature;
a cooling plate having one or more cooling features configured to selectively cool the cooling plate to a cooling plate temperature; and
a vacuum chamber operably coupled to the platen and the cooling plate, wherein the vacuum chamber defines a chamber volume between the platen and the cooling plate;
a vacuum source selectively fluidly coupled to the chamber volume;
a gas source selectively fluidly coupled to the chamber volume and configured to selectively supply a gas thereto;
a vacuum chamber valve, wherein the vacuum chamber valve selectively fluidly couples the chamber volume to each of the vacuum source and the gas source; and
a controller configured to control the platen temperature in a high temperature regime and a low temperature regime via a control of the one or more heating elements, wherein the controller is further configured to control a pressure within the vacuum chamber via a control of the vacuum chamber valve, thereby selectively controlling a heat transfer between the platen and the cooling plate in the high temperature regime and the low temperature regime.

17. The ion implantation system of claim 16, wherein the vacuum chamber comprises one or more radiation shields disposed within the chamber volume, and wherein the one or more radiation shields are configured to limit a radiative heat transfer between the platen and the cooling plate.

18. The ion implantation system of claim 16, wherein the high temperature regime is greater than approximately 200° C., and wherein the low temperature regime is between approximately room temperature and approximately 100° C.

19. The ion implantation system of claim 16, wherein the workpiece clamp comprises an electrostatic clamp having one or more electrodes associated with the platen, wherein the electrostatic clamp is configured to selectively electrostatically attract the workpiece to the support surface of the platen based on an electrical current supplied to the one or more electrodes.

20. The ion implantation system of claim 16, wherein the controller is further configured to selectively evacuate the vacuum chamber when the platen temperature is in the high temperature regime, thereby minimizing convective heat transfer and conductive heat transfer between the platen and the cooling plate.

21. The ion implantation system of claim 16, wherein the vacuum chamber comprises a chamber conduit operably coupled to the vacuum chamber valve, wherein the vacuum chamber valve is configured to selectively fluidly couple the chamber volume to each of the vacuum source and the gas source via the chamber conduit.

22. The ion implantation system of claim 21, wherein the vacuum source comprises a vacuum environment defined within the end station.

23. The ion implantation system of claim 16, wherein the vacuum source comprises a vacuum pump.

24. The ion implantation system of claim 16, wherein the controller is further configured to selectively supply the gas from the gas source to the vacuum chamber at a predetermined pressure when the platen temperature is in the low temperature regime, thereby effectuating convective heat transfer and conductive heat transfer between the platen and the cooling plate.

25. The ion implantation system of claim 24, wherein the predetermined pressure is greater than approximately 5 torr.

26. The ion implantation system of claim 16, wherein the gas comprises a thermally conductive gas.

27. The ion implantation system of claim 16, wherein the one or more cooling features comprise one or more cooling channels defined in the cooling plate, and wherein the ion implantation system further comprises a cooling fluid source configured to supply a cooling fluid to the one or more cooling channels.

28. The ion implantation system of claim 16, further comprising a manipulator apparatus and a mounting flange, wherein the cooling plate is operably coupled to the manipulator apparatus via the mounting flange, and wherein the manipulator apparatus is configured to selectively translate the workpiece clamp.

29. A method for controlling temperature in semiconductor processing, the method comprising:
selecting an operation of the semiconductor processing in one of a high temperature regime and a low temperature regime;
placing a workpiece on a platen of a workpiece clamp, wherein the workpiece clamp comprises a vacuum chamber disposed between the platen and a cooling plate thereof, and wherein the vacuum chamber comprises a chamber volume having one or more radiation shields disposed therein;
cooling the cooling plate to a predetermined cooling temperature;
clamping the workpiece to the platen;
evacuating the vacuum chamber when the operation of the semiconductor processing is in the high temperature regime to define a vacuum within the chamber volume, thereby thermally isolating the cooling plate from the platen via the vacuum within the chamber volume and the one or more radiation shields;
supplying a conductive gas to the chamber volume when the operation of the semiconductor processing is in the low temperature regime, thereby effectuating thermal conduction and thermal convection between the platen and the cooling plate; and
processing the workpiece through a process medium.

30. The method of claim 29, wherein the process medium comprises an ion beam.

31. The method of claim 29, wherein the high temperature regime is greater than approximately 200° C. and wherein the low temperature regime is between approximately room temperature and approximately 100° C.
